(19) United States
(12) Patent Application Publication
(10) Pub. No.: US 2002/0106895 A1
(43) Pub. Date: Aug. 8, 2002

(54) Method for forming copper interconnect and enhancing electromigration resistance

(75) Inventor: Wei-Ming Chung, Taipei City (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/778,266

(22) Filed: Feb. 8, 2001

(51) Int. Cl. H01L 21/44

(52) U.S. Cl. 438/687

(57) ABSTRACT

In prior multi-level copper interconnects manufacturing a barrier metal layer is needed, but it will decrease the electromigration resistance and degrade the reliability. Therefore, in present invention we provide a method for forming high-reliability interconnect. The main step is using an etching step to remove the barrier metal layer positioned between plugs and interconnects. Firstly, there is a first copper interconnect formed over a substrate. Then a barrier dielectric layer, a first inter-metal dielectric layer, an etch stop layer and a second inter-metal dielectric layer are stepwise formed over the first copper interconnect. Then, a barrier layer is deposited over the second inter-metal dielectric layer. A dual damascene opening is formed by patterning and etching, and the opening consists of a line opening for interconnect and a via hole. Then, a barrier metal layer is conformally deposited on the surface of the dual damascene opening. A partial region of the barrier metal layer between the via hole and the first copper interconnect is etched to expose a partial region of the first copper interconnect. Finally, metal copper is deposited to from a dual damascene structure, so that multi-level interconnects are completed.

### BACKGROUND

1.Field of the Invention

The present invention generally relates to a method for forming a copper interconnect, and in particular to a method for forming a copper interconnect with high electromigration resistance.

2.Description of the Prior Art

In conventional VLSI process, the popular conductive material used for the contacts and interconnects comprises Al—Cu—Si alloy and metal tungsten. There is usually a layer of titanium nitride or tungsten nitride between an interconnect and a dielectric layer, which is used to improve the adhesion of metal layer to other material or to avoid the metal silicide formed in the interface of metal layer and silicon layer.

Copper metallization has become a future trend in integrated circuit manufacturing. As the feature sizes are scaled down, the performance of internal devices in integrated circuits becomes more dependent upon the propagation speed of the signals along the interconnects that connect the various devices together. Copper is preferred for its low resistivity. Unfortunately, copper contamination of the inter-metal dielectric (IMD) layer is a problem. Copper suffers from high diffusion in common insulation materials such as silicon oxide, and oxygen-containing polymers. The attendant serious problems such as loss of adhesion, delamination, voids, line shorts and device performance degradation can eventually lead to a catastrophic failure of the circuitry. It is preferred to prevent the copper contamination of the inter-metal dielectric layer. A copper diffusion barrier layer is therefore often required. The useful copper diffusion barrier layer comprises barrier dielectric layer, such as silicon nitride (SiNx) and silicon carbide (SiC), and barrier metal layer, such as tantalum nitride (TaNx), titanium nitride (TiNx) and tungsten nitride (WNx).

The dual damascene process is an important method to manufacture multi-level interconnects, and is also a suitable method to manufacture the copper interconnects. The prior copper-based dual damascene structure is shown in FIG. 1. There is a first copper interconnect 101 in FIG. 1, and a barrier dielectric layer 102, a first inter-metal dielectric layer 103, an etch stop layer 104 and a second inter-metal dielectric layer 105 are stepwise formed over the first copper interconnect 101. The dual damascene structure 107 consists of a second copper interconnect 107A and a copper plug 107B, and there is a barrier metal layer 106 formed on the surface of the dual damascene structure 107.

There are two ways for forming a dual damascene opening: one is to form the line opening for interconnect firstly, and then to form the via hole, as shown in FIG. 3A to FIG. 3E; the other is in reverse order to form the via hole firstly, and then to form the line opening, as shown in FIG. 4A to FIG. 4E. In the first way, as shown in FIG. 3A, there is a first copper interconnect 301 on the substrate (not shown). And two inter-metal dielectric layers are formed over the first copper interconnect 301: one is the first inter-metal dielectric layer 303 and the other is the second inter-metal dielectric layer 305. A barrier dielectric layer 302 which is formed between the first copper interconnect 301 and the first inter-metal dielectric layer 303 is needed to avoid that the metal copper diffuses into the inter-metal dielectric layer 303. And there is an etch stop layer 304 existed between the first inter-metal dielectric layer 303 and the second inter-metal dielectric layer 305.

A first photoresist 306 is then formed on the second inter-metal dielectric layer 305, and is patterned to define a second copper interconnect. Secondly, the second inter-metal dielectric layer 305 is etched to form a line opening 307, as shown in FIG. 3B. Then. the first photoresist 306 is removed, and a second photoresist 308 is deposited, and is then patterned to define a via hole, as shown in FIG. 3C. An etching is used to remove partial etch stop layer 304, partial first inter-metal dielectric layer 303, and partial barrier dielectric layer 302 to form a via hole 309, as shown in FIG. 3D. And then the second photoresist 308 is also removed. A barrier metal layer 310 is conformally deposited on the surface of the line opening 307 and the via hole 309 to form a dual damascene opening 311, as shown in FIG. 3E. Such dual damascene opening 311 consists of a line opening 311A and via hole 311B. Finally, a dual damascene structure 107, as shown in FIG. 1, is formed by depositing metal copper to fill the dual damascene opening 311, and a chemical-mechanical polishing process remove the redundant copper and barrier metal.

In the second way, as shown in FIG. 4A, there is a first copper interconnect 401 on the substrate (not shown). And two inter-metal dielectric layers are formed over the first copper interconnect 401: one is the first inter-metal dielectric layer 403 and the other is the second inter-metal dielectric layer 405. A barrier dielectric layer 402 is formed between the first copper interconnect 401 and the first inter-metal dielectric layer 403. And there is an etch stop layer 404 existed between the first inter-metal dielectric layer 403 and the second inter-metal dielectric layer 405. A first photoresist 406 is then formed on the second inter-metal dielectric layer 405, and is patterned to define a via hole. Next, an etching is used to remove partial second inter-metal dielectric layer 405, partial etch stop layer 404, partial first inter-metal dielectric layer 403, and partial barrier dielectric layer 402, so that a via hole 407 is formed, as shown in FIG. 4B. Then, the first photoresist 406 is removed, and a second photoresist 408 is deposited, and is then patterned to define a second interconnect, as shown in FIG.4C. An etching is then used to remove partial second inter-metal dielectric layer 405, so that a line opening 409A and a via hole 409B are formed, as shown in FIG. 4D. Finally, the second photoresist 408 is also removed. A barrier metal layer 410 is conformally deposited on the surface of the line opening 409A and the via hole 409B to form a dual damascene opening 411, as shown in FIG. 4E. Such dual damascene opening 411 consists of a line opening 411A and via hole 411B.

The copper interconnects and plugs can be separated from the inter-metal dielectric layer by a barrier metal layer, but an unwanted section of barrier metal layer is also existed between the copper plug 107B and the copper interconnect 101, as shown in FIG. 1. Such section of barrier metal layer adds interfaces between interconnects, and will degrade the electromigration resistance of interconnects. In order to manufacture a more reliable interconnect, the electromigration resistance which is reduced by the material discontinuity should be enhanced.

### SUMMARY

It is an object of the invention to provide a method for manufacturing a high-reliability interconnect.

It is another object of the invention to provide a method for removing the barrier metal layer between the copper interconnects.

It is a further object of the invention to provide a method for enhancing the electromigration resistance between the copper interconnects.

According to the foregoing objects, the present invention provides a method to remove the barrier metal layer between the interconnects and the plugs by primarily using an etching step. Firstly, there is a first copper interconnect over a substrate. Next, a barrier dielectric layer, a first inter-metal dielectric layer, an etch stop layer, and a second inter-metal dielectric layer are stepwise formed on the first copper interconnect. Then, a barrier layer is deposited on the second inter-metal dielectric layer. The barrier layer can be a metal, such as tantalum nitride, titanium nitride, and tungsten nitride, or a dielectric, such as silicon nitride and silicon carbide. Then, the patterning and etching techniques are used to form a dual damascene opening which consists of a line opening for interconnect and a via hole. Like the prior art method, there are two ways to form a dual damascene opening: one is to form the line opening first, and then to form the via hole; the other is in reverse order to form the via hole first, and then to form the line opening. Next, a barrier metal layer is conformally deposited on the surface of the dual damascene opening. An etching, such as plasma etching, is then used to remove the region of the second barrier metal layer positioned between the via hole and the first copper interconnect, so that the first copper interconnect is partially exposed. Finally, copper is deposited to form a dual damascene structure. A chemical-mechanical polishing process is used to remove the redundant copper and barrier metal. The multi-level interconnect is then completed.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 shows a schematic cross-sectional diagram of a prior copper interconnect with a dual damascene structure;

FIG. 2 shows a schematic cross-sectional diagram of a copper interconnect with a dual damascene structure on which a plurality of vertical barrier metal segments are formed;

FIG. 3A through FIG. 3E provide cross-sectional views at various stages of a way to form a dual damascene opening;

FIG.4A through FIG.4E provide cross-sectional views at various stages of another way to form a dual damascene opening;

FIG. 5A through FIG. 5H provide cross-sectional views at various stages of a prefer embodiment fabrication flow of a copper interconnect with a dual damascene structure on which a plurality of vertical barrier metal segments are formed.

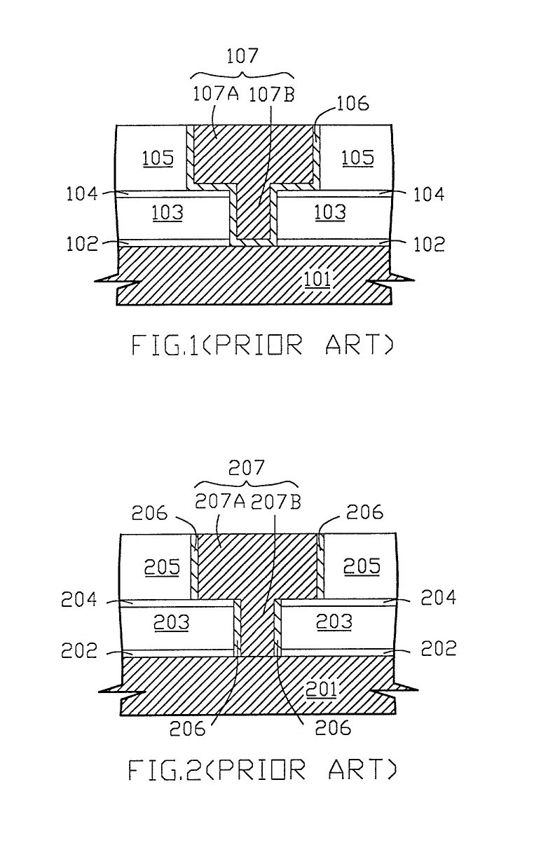

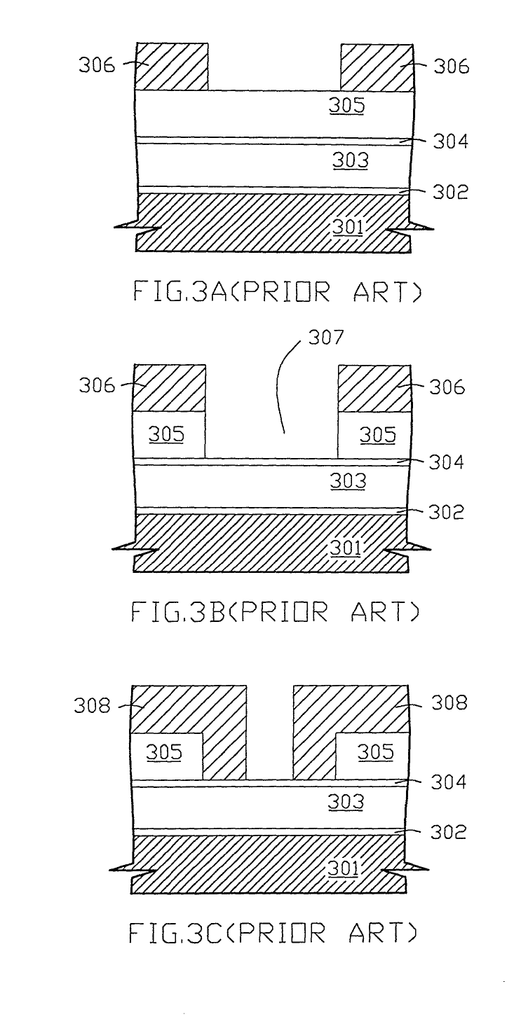

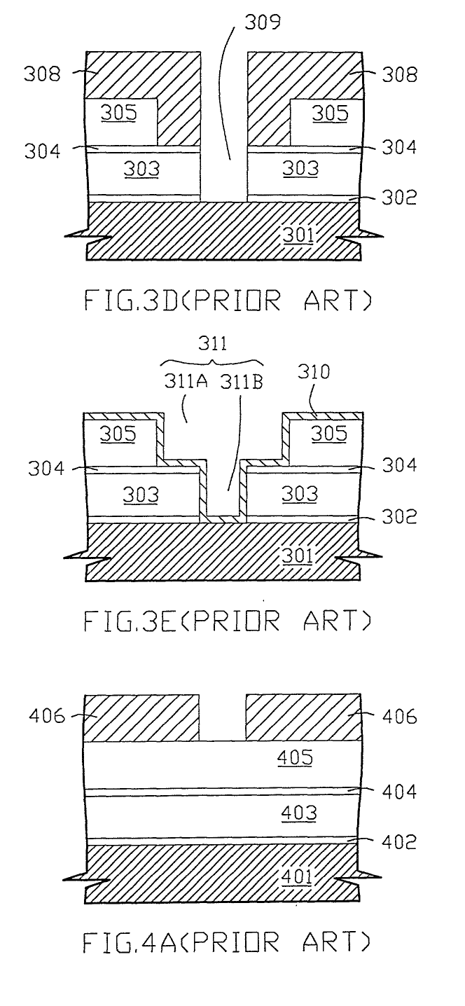

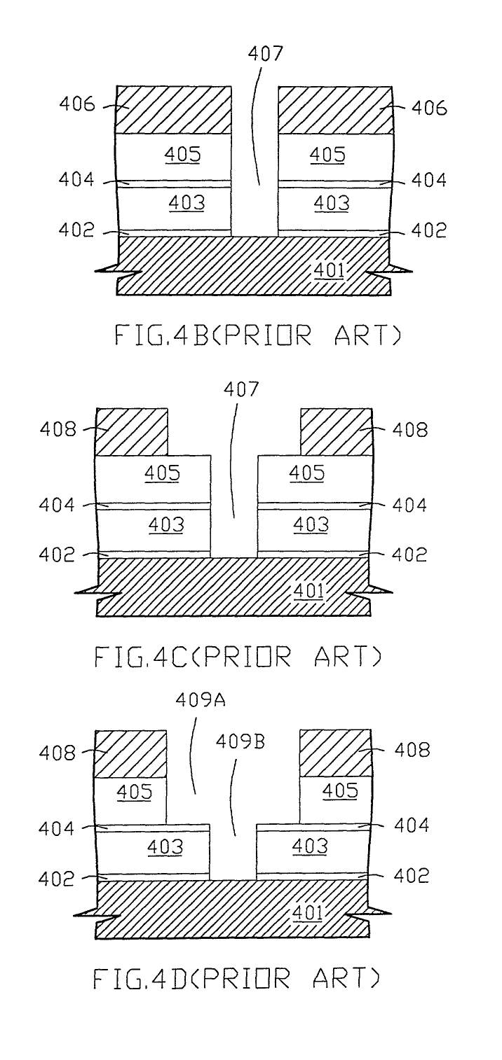

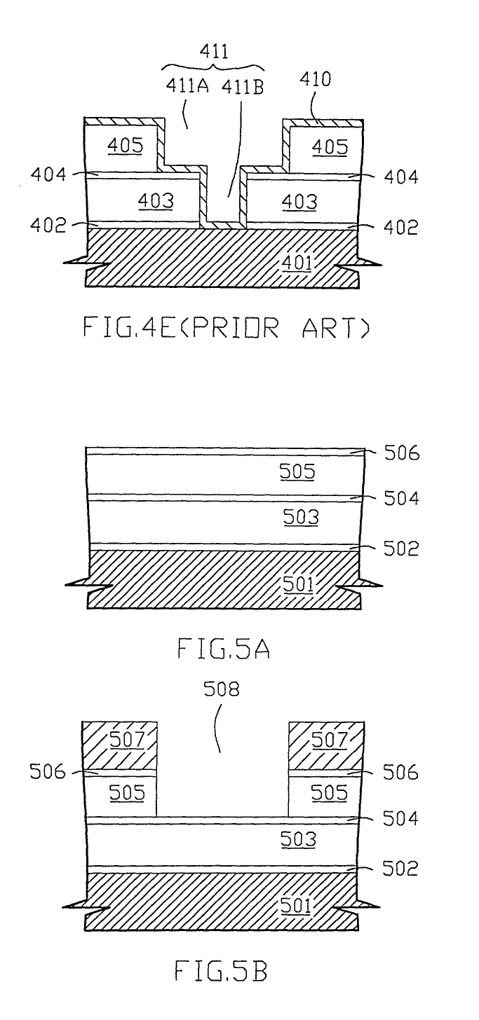

### DESCRIPTION OF THE PREFERRED EMBODIMENT

The primary point of present invention is to remove the partial region of barrier metal layer between the copper interconnects and plugs, so that no unwanted interface is existed.

As shown in FIG. 2, there are barrier metal layers 206 existed between the inter-metal dielectric layer 205 and interconnect 207A as well as between the inter-metal dielectric layer 203 and plug 207B. But no barrier metal layer is existed between the copper interconnect 201 and copper plug 207B.

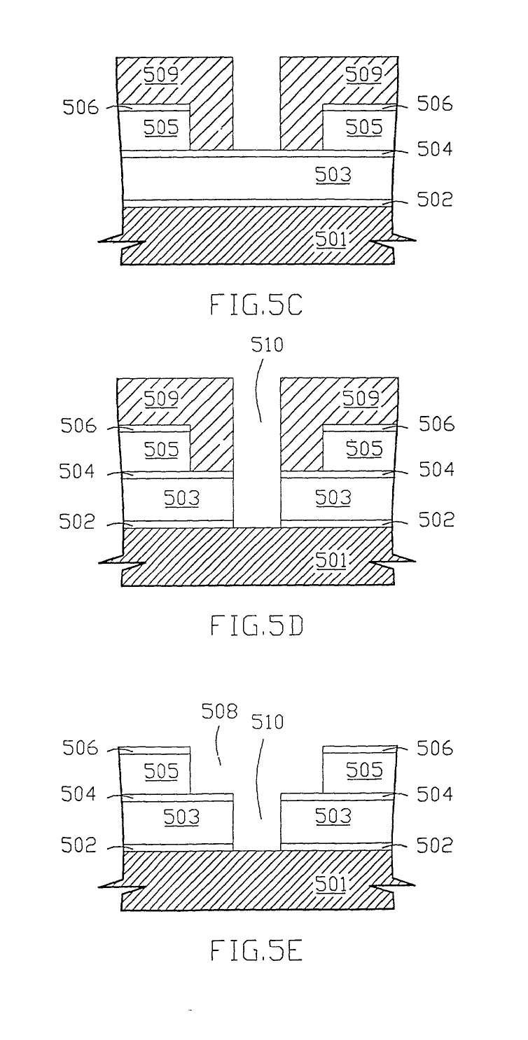

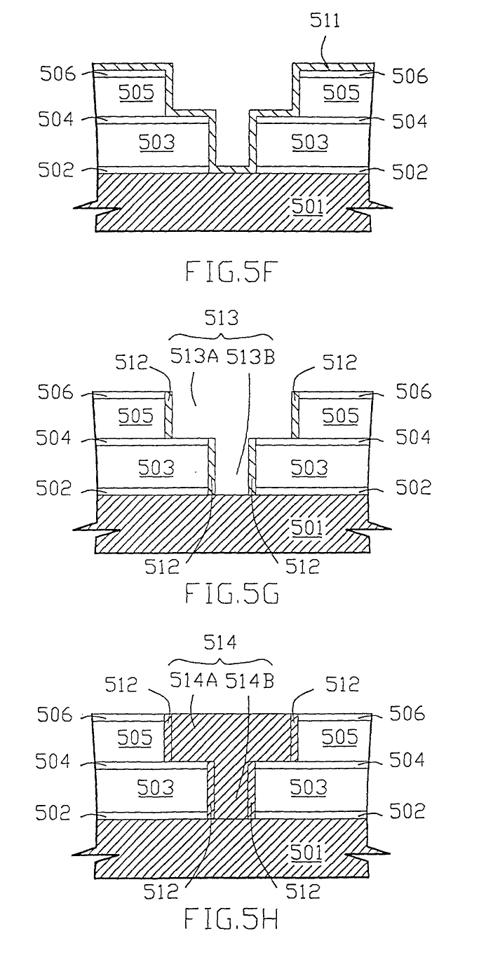

A preferred embodiment in present invention is shown in FIG. 5A through FIG. 5H. Firstly, as shown in FIG. 5A, there is a first copper interconnect 501 formed over a substrate (not shown). Then, a barrier dielectric layer 502, a first inter-metal dielectric layer 503, an etch stop layer 504, a second inter-metal dielectric layer 505, and a barrier layer 506 are stepwise formed over the first copper interconnect 501. The barrier layer 506 can be a metal, such as tantalum nitride, titanium nitride, and tungsten nitride, or a dielectric, such as silicon nitride and silicon carbide.

Secondly, a photoresist 507 is formed on the barrier layer 506, and is patterned to define a second interconnect. An etching is then used to remove partial second inter-metal dielectric layer 505 and partial barrier layer 506, so that a line opening 508 is formed, as shown in FIG.5B. The first photoresist 507 is then removed, and a second photoresist 509 is consequently formed and patterned to define a via hole, as shown in FIG. 5C. Another etching is used to remove partial etch stop layer 504, partial first inter-metal dielectric layer 503, and partial barrier dielectric layer 502, so that a via hole 510 is formed, as shown in FIG. 5D. Then, the second photoresist 509 is removed, and a dual damascene opening which consists of a line opening 508 and a via hole 510 is formed, as shown in FIG. 5E.

Next, a barrier metal layer 511 is conformally deposited on the surface of the line opening 508 and the via hole 510, as shown in FIG. 5F. Then, a plasma etching is used to remove the horizontal part of the barrier metal layer 511 and leave the vertical part 512 of the barrier metal layer 511. Hence, a dual damascene opening 513 which consists of the line opening 513A and the via hole 513B is formed, and there is no barrier layer existed between the via hole 513B and the first copper interconnect 501, as shown in FIG. 5G. One point needs to be made. If the barrier layer 506 is a metal, an overetch of barrier metal layer 511 should be optimized so that the barrier layer 506 is not totally removed. Certainly, the material of the etch stop layer 504 is selected from which can resist the plasma etching.

Finally, depositing metal copper is used to form a dual damascene structure 514 which consists of a second copper interconnect 514A and a copper plug 514B, as shown in FIG. 5H. In addition, a chemical-mechanical polishing (CMP) process is used to remove the redundant copper and barrier metal. A multi-level copper interconnect formed according to the present invention can enhance the electromigration resistance by the absence of barrier metal layers between copper interconnects and plugs. Therefore, such interconnect is more reliable.

In this embodiment, the way of forming a dual damascene opening is firstly forming the line opening for interconnect and then forming the via hole. However, a way of firstly forming the via hole and then forming the line opening can also be used. Such is still within this present invention.

Although specific embodiments have been illustrated and described, it will be obvious to those skilled in the art that various modifications may be made without departing from what is intended to be limited solely by the appended claims.

What is claimed is:

1. A method for forming copper interconnect, said method comprising the steps of:
providing a structure, wherein said structure comprises a first copper interconnect, a barrier dielectric layer formed over said first copper interconnect, a first inter-metal dielectric layer formed over said barrier dielectric layer, an etch stop layer formed over said first inter-metal dielectric layer, a second inter-metal dielectric layer formed over said etch stop layer, and a barrier layer formed over said second inter-metal dielectric layer
forming a dual damascene opening by patterning and etching to remove partial said barrier layer, partial said second inter-metal dielectric layer, partial said etch stop layer, partial said first inter-metal dielectric layer, and partial said barrier dielectric layer;
conformally depositing a barrier metal layer on the surface of said dual damascene opening, wherein said barrier metal layer consists of a plurality of horizontal barrier metal segments and a plurality of vertical barrier metal segments;
etching a partial region of said plurality of horizontal barrier metal segments positioned over the surface of said first copper interconnect to expose a partial region of said first copper interconnect; and
depositing copper to fill said dual damascene opening, so that a second copper interconnect and a copper plug are formed.

2. The method according to claim 1, wherein the step of forming a dual damascene opening by patterning and etching comprises the steps of:
first patterning and etching to remove partial said barrier layer and partial said second inter-metal dielectric layer, so that a line opening is formed; and
second patterning and etching to remove partial said etch stop layer, partial said first inter-metal dielectric layer and partial said barrier dielectric layer, so that a via hole is formed.

3. The method according to claim 1, wherein the step of forming a dual damascene opening by patterning and etching comprises the steps of:
first patterning and etching to remove partial said barrier layer, partial said second inter-metal dielectric layer, partial said etch stop layer, partial said first inter-metal dielectric layer, and partial said barrier dielectric layer, so that a via hole is formed; and
second patterning and etching to remove partial said barrier layer, and partial said second inter-metal dielectric layer, so that a line opening is formed.

4. The method according to claim 1, wherein the material of said barrier dielectric layer comprises silicon nitride.

5. The method according to claim 1, wherein the material of said barrier dielectric layer comprises silicon carbide.

6. The method according to claim 1, wherein said barrier layer is a layer of metal selected from the group consisting of tantalum nitride, titanium nitride, and tungsten nitride.

7. The method according to claim 1, wherein said barrier layer is a dielectric layer.

8. The method according to claim 7, wherein the material of said dielectric layer comprises silicon nitride.

9. The method according to claim 7, wherein the material of said dielectric layer comprises silicon carbide.

10. The method according to claim 1, said method further comprising a chemical mechanical polishing process to remove a region of said second copper interconnect and said barrier metal layer over said barrier layer.

11. A method for forming copper interconnect, said method comprising the steps of:
providing a substance;
forming a first copper interconnect over said substrate;
forming a barrier dielectric layer over said first copper interconnect;
forming a first inter-metal dielectric layer over said barrier dielectric layer;
forming an etch stop layer over said first inter-metal dielectric layer;
forming a second inter-metal dielectric layer over said etch stop layer;
forming a barrier layer over said second inter-metal dielectric layer;
forming a dual damascene opening by patterning and etching to remove partial said barrier layer, partial said second inter-metal dielectric layer, partial said etch stop layer, partial said first inter-metal dielectric layer, and partial said barrier dielectric layer;
conformally depositing a barrier metal layer on the surface of said dual damascene opening, wherein said barrier metal layer consists of a plurality of horizontal barrier metal segments and a plurality of vertical barrier metal segments;
etching a partial region of said plurality of horizontal barrier metal segments positioned over the surface of said first copper interconnect to expose a partial region of said first copper interconnect; and
depositing copper to fill said dual damascene opening, so that a second copper interconnect and a copper plug are formed.

12. The method according to claim 11, wherein the step of forming a dual damascene opening by patterning and etching comprises the steps of:
first patterning and etching to remove partial said barrier layer and partial said second inter-metal dielectric layer, so that a line opening is formed; and
second patterning and etching to remove partial said etch stop layer, partial said first inter-metal dielectric layer and partial said barrier dielectric layer, so that a via hole is formed.

13. The method according to claim 11, wherein the step of forming a dual damascene opening by patterning and etching comprises the steps of:
first patterning and etching to remove partial said barrier layer, partial said second inter-metal dielectric layer, partial said etch stop layer, partial said first inter-metal dielectric layer, and partial said barrier dielectric layer, so that a via hole is formed; and
second patterning and etching to remove partial said barrier layer, and partial said second inter-metal dielectric layer, so that a line opening is formed.

14. The method according to claim 11, wherein the material of said barrier dielectric layer comprises silicon nitride.

15. The method according to claim 11, wherein the material of said barrier dielectric layer comprises silicon carbide.

16. The method according to claim 11, wherein said barrier layer is a layer of metal selected from the group consisting of tantalum nitride, titanium nitride, and tungsten nitride.

17. The method according to claim 11, wherein said barrier layer is a dielectric layer.

18. The method according to claim 17, wherein the material of said dielectric layer comprises silicon nitride.

19. The method according to claim 17, wherein the material of said dielectric layer comprises silicon carbide.

20. The method according to claim 11, said method further comprising a chemical mechanical polishing process to remove a region of said second copper interconnect and said barrier metal layer over said barrier layer.
